(19) United States
(12) Patent Application Publication
(10) Pub. No.: US 2023/0050969 A1
(43) Pub. Date: Feb. 16, 2023

(54) PACKAGE-ON-PACKAGE AND PACKAGE MODULE INCLUDING THE SAME

(71) Applicant: SAMSUNG ELECTRONICS CO., LTD., Suwon-si (KR)

(72) Inventors: Heungkyu KWON, Seongnam-si (KR); Heejung CHOI, Seongnam-si (KR); Kyojin HWANG, Hwaseong-si (KR)

(73) Assignee: SAMSUNG ELECTRONICS CO., LTD., Suwon-si (KR)

(21) Appl. No.: 17/884,143

(22) Filed: Aug. 9, 2022

(30) Foreign Application Priority Data
Aug. 10, 2021 (KR) 10-2021-0105486
Jun. 8, 2022 (KR) 10-2022-0069700

(51) Int. Cl. H01L 25/18; H01L 23/498; H01L 23/538; H01L 23/31; H01L 23/00

(52) U.S. Cl. CPC H01L 25/18; H01L 23/49816; H01L 23/5389; H01L 23/5386; H01L 23/3128; H01L 24/16; H01L 24/48; H01L 2224/16225; H01L 2224/48225; H01L 23/481

(57) ABSTRACT

Provided is a package-on-package (PoP). The PoP includes a lower package, an upper package on the lower package, an interposer substrate disposed between the lower package and the upper package, and a plurality of balls connecting the interposer substrate to the upper package, in which the lower package includes a first substrate, and a first die and a second die disposed side by side in a horizontal direction, on the first substrate, in which the upper package includes a second substrate, a third die on the second substrate, and a plurality of ball pads disposed on a surface of the second substrate, the interposer substrate comprises on a surface thereof a plurality of ball lands to which a plurality of balls are attached, and at least some of the plurality of ball lands overlap the first die and the second die in a vertical direction that intersects the horizontal direction.

### CROSS-REFERENCE TO RELATED APPLICATIONS

This application is based on and claims priority under 35 U. S. C. § 119 to Korean Patent Application No. 10-2021-0105486, filed on Aug. 10, 2021, in the Korean Intellectual Property Office, and Korean Patent Application No. 10-2022-0069700, filed on Jun. 8, 2022, in the Korean Intellectual Property Office, the disclosures of which are incorporated by reference herein in their entireties.

### BACKGROUND

The exemplary embodiments relate to a package-on-package and a package module including the same, and more particularly, to a package-on-package that includes an interposer substrate between a lower package and an upper package and a package module including the package-on-package.

As the use of portable devices such as smart phones and tablet personal computers (PCs) has recently increased, manufacturers for manufacturing the portable devices have developed the portable devices having light weights and small sizes. For the portable devices, a number of integrated circuits are used, each of which is packaged as a semiconductor package. A package-on-package (PoP) has become essential for the manufacture of smartphones and tablet PCs in order to save the amount of space taken up by a system board and to reduce the size of portable electronic devices. To this end, a PoP has been developed in which a memory package (e.g., an upper package) is stacked on a logic package (e.g., a lower package) to reduce a surface area of a printed circuit board (PCB).

In particular, when an application processor (AP) and a modem are respectively manufactured in a single system on chip (SoC) in implementation of a Modern Application Processor PoP (“ModAP PoP”), a modem system in package (SiP) needs to be further mounted on a system board, increasing the size of the system board and thus reducing the amount of space available for a battery. To solve this problem, a PoP which does not increase a mounting area on the system board has been developed.

### SUMMARY

Aspects of the present disclosure provides a package-on-package (PoP) which reduces a mounting area on a system board.

Aspects of the present disclosure also provides a PoP which increases convenience in use.

Further, aspects of the present disclosure provides a package module which reduces a size of a system board, thus having a reduced size.

Additionally, aspects of the present disclosure also provides a package module including a PoP which increases convenience in use.

The aspects of the present disclosure are not limited to those mentioned above, and other aspects not mentioned will be clearly understood by those of ordinary skill in the art from the description provided below.

For the above aspects, the disclosure provides a PoP. A PoP according to an embodiment includes a lower package, an upper package on the lower package, an interposer substrate disposed between the lower package and the upper package, and a plurality of balls connecting the interposer substrate to the upper package, in which the lower package includes a first substrate, a first die and a second die disposed side by side in a horizontal direction, on the first substrate, a vertical connection member electrically connecting the first substrate to the interposer substrate, between the first substrate and the interposer substrate, and a molding layer covering the first die, the second die, and the vertical connection member, in which the upper package includes a second substrate, a third die on the second substrate, and a plurality of ball pads disposed on a surface of the second substrate to correspond to a package ball map comprising cells forming a plurality of rows and a plurality of columns, wherein one signal is placed in each of the cells, in which the plurality of balls are attached on a bottom surface of the plurality of ball pads, the interposer substrate comprises on a surface thereof a plurality of ball lands to which the plurality of balls are attached, and at least some of the plurality of ball lands overlap the first die and the second die in a vertical direction that intersects the horizontal direction.

To solve the aspects, the disclosure provides a PoP. A PoP according to an embodiment of the disclosure includes a lower package, an upper package on the lower package, an interposer substrate disposed between the lower package and the upper package, and a plurality of balls connecting the interposer substrate to the upper package, in which the lower package includes a first substrate, a first die and a second die disposed side by side in a horizontal direction, on the first substrate, a vertical connection member electrically connecting the first substrate to the interposer substrate, between the first substrate and the interposer substrate, and a molding layer covering the first die, the second die, and the vertical connection member, in which the upper package includes a second substrate, a third die on the second substrate, and a plurality of ball pads disposed on a surface of the second substrate to correspond to a package ball map comprising cells forming a plurality of rows and a plurality of columns, in which one signal is placed in each of the cells, in which the plurality of balls are attached on a bottom surface of the plurality of ball pads, the interposer substrate comprises on a surface thereof a plurality of ball lands to which the plurality of balls are attached, and a data signal and/or a control signal of the third die are transmitted and received through the vertical connection member, and the data signal and/or the control signal of the third die transmitted and received through the vertical connection member are not electrically connected to the first die and the second die in the interposer substrate and the lower package, and at least some of the ball lands overlap the first die and the second die in a vertical direction.

To solve the technical problems, the disclosure provides a package module. A package module according to an embodiment of the disclosure includes a system board and a first package and a second package attached to the system board, in which the first package includes a first lower package, a first upper package disposed on the first lower package, and a first interposer substrate disposed between the first lower package and the first upper package, and the second package includes a second lower package, a second upper package disposed on the second lower package, and a second interposer substrate disposed between the second lower package and the second upper package, and the first lower package includes a first substrate, a first die and a second die disposed on the first substrate, and a first vertical connection member electrically connecting the first substrate to the interposer substrate, between the first substrate and the interposer substrate, and the first upper package includes a second substrate and a third die on the second substrate, and the second lower package includes a third substrate, a fourth die stacked on the third substrate, and a second vertical connection member electrically connecting the third substrate to the second interposer substrate, between the third substrate and the second interposer substrate, and the second upper package includes a fourth substrate and a fifth die on the fourth substrate, and the system board includes a first zone in which some of a plurality of first pads for connection to the first substrate are disposed, a second zone in which some others of the plurality of first pads are disposed, a third zone in which some of a plurality of second pads for connection to the third substrate are disposed, and a fourth zone in which some others of the plurality of second pads are disposed, and the first zone and the third zone are connected by first routing in the system board, and the second zone and the fourth zone are connected by second routing in the system board, and the first routing and the second routing do not intersect each other.

### BRIEF DESCRIPTION OF THE DRAWINGS

Embodiments of the disclosure will be more clearly understood from the following detailed description taken in conjunction with the accompanying drawings in which:

FIGS. 1A and 1B are cross-sectional views of package-on-packages (PoPs) according to embodiments of the disclosure;

FIG. 1C is a plane view of an interposer substrate of PoPs according to embodiments of the disclosure;

FIG. 1D is a plane view of a substrate of an upper package of PoPs according to embodiments of the disclosure;

FIGS. 2 and 3A are cross-sectional views PoPs according to embodiments of the disclosure;

FIGS. 3B and 3C are schematic plane views of some components of PoPs according to embodiments of the disclosure shown in FIGS. 1A and 3A;

FIGS. 4, 5, 6A, 6B, 7 to 10 are cross-sectional views of PoPs according to embodiments of the disclosure;

FIGS. 11 and 12 are cross-sectional views of PoPs according to embodiments of the disclosure;

FIG. 13A is a cross-sectional view of a package module according to an embodiment of the disclosure;

FIG. 13B is a schematic plane view of some components of a package module according to embodiments of the disclosure shown in FIG. 13A;

FIG. 13C is a perspective view schematically showing some components including a system board of a package module according to an embodiment of the disclosure shown in FIG. 13A;

FIG. 14A is a cross-sectional view of a package module according to another embodiment of the disclosure;

FIGS. 14B and 14C are schematic plane views of some components of a package module according to embodiments of the disclosure shown in FIG. 14A; and

FIG. 14D is a cross-sectional view viewed from a direction different from a package module according to an embodiment of the disclosure shown in FIG. 14A.

### DETAILED DESCRIPTION OF THE EMBODIMENTS

To fully understand the configuration and effect of the inventive concept, embodiments of the inventive concept will be described with reference to the accompanying drawings. However, the inventive concept is not limited to the embodiments disclosed below, but may be implemented in various forms and various changes may be made thereto. A description of the current embodiments are provided to complete the disclosure of the inventive concept and perfectly inform those of ordinary skill in the art of the scope of the inventive concept. In the accompanying drawings, components are shown exaggerated in size for convenience of explanation and proportions of each component may be exaggerated or reduced.

Terms used in embodiments of the inventive concept may be interpreted as meanings typically known to those of ordinary skill in the art, unless defined otherwise.

Hereinafter, the inventive concept will be described in detail by describing embodiments of the inventive concept with reference to the accompanying drawings.

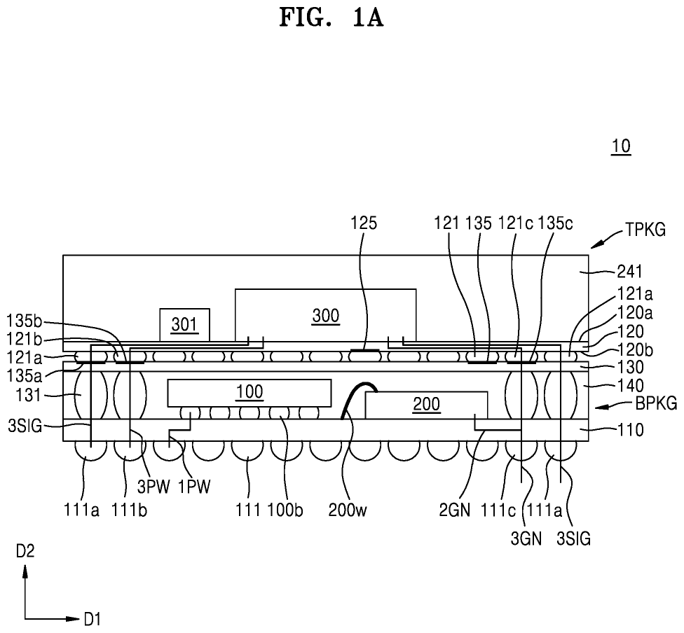

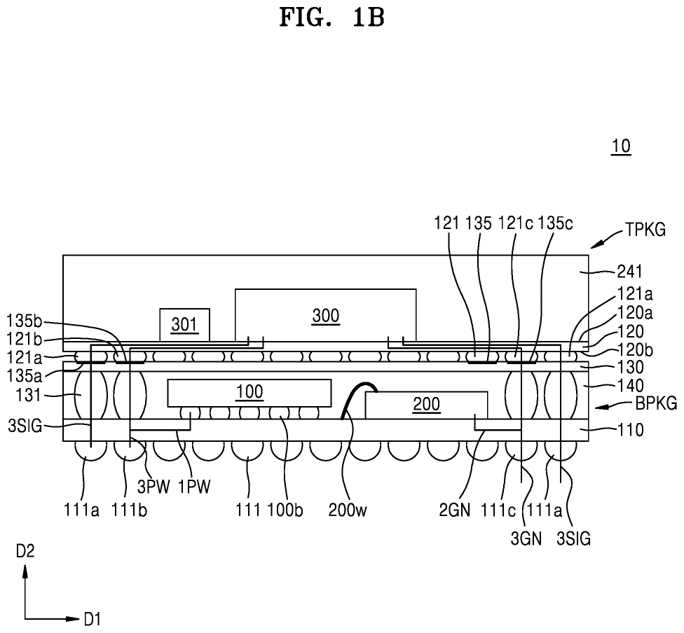

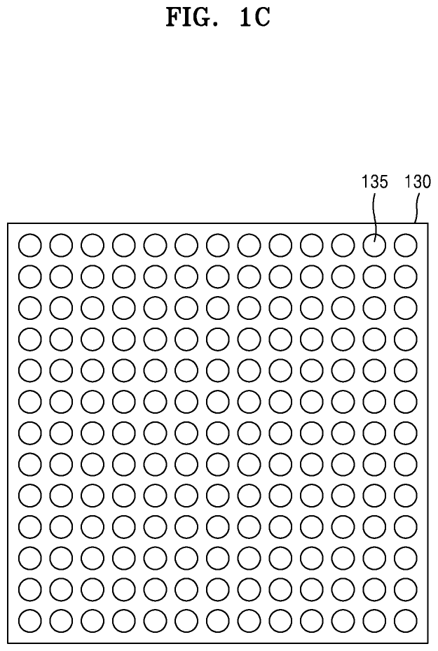

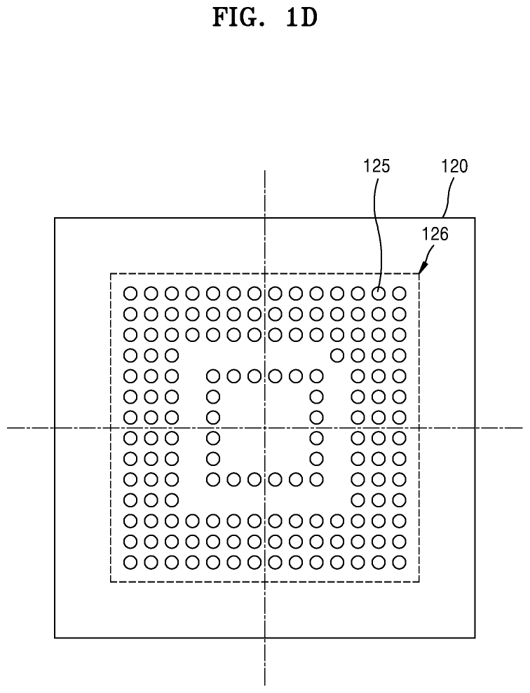

FIGS. 1A and 1B are cross-sectional views of package-on-packages (PoPs) according to embodiments of the disclosure. FIG. 1C is a plane view of an interposer substrate of PoPs according to embodiments of the disclosure. FIG. 1D is a plane view of a substrate of an upper package of PoPs according to embodiments of the disclosure.

Referring to FIGS. 1A, 1C, and 1D together, a PoP 10 according to an embodiment of the disclosure may include a lower package BPKG, an upper package TPKG, and an interposer substrate 130 disposed between the lower package BPKG and the upper package TPKG.

The lower package BPKG may include a first substrate 110, a first die 100 and a second die 200 disposed side by side in a horizontal direction D1 on the first substrate 110, e.g., co-planarly disposed on the first substrate 110, a vertical connection member 131 electrically connecting the first substrate 110 to the interposer substrate 130 and disposed between the first substrate 110 and the interposer substrate 130, and a molding layer 140 that covers the first die 100, the second die 200, and the vertical connection member 131.

More specifically, the first die 100 and the second die 200 may be attached to a top surface of the first substrate 110.

The first substrate 110 may include a printed circuit board (PCB) or a redistributed layer (RDL). In some embodiments, the PCB may be a multi-layer PCB having a substrate base with a plurality of base layers stacked. In some embodiments, each of the plurality of base layers forming the substrate base may include at least one material selected from among phenol resin, epoxy resin, and polyimide. For example, each of the plurality of base layers forming the substrate base may include at least one material selected from among a frame retardant 4 (FR4), tetrafunctional epoxy, polyphenylene ether, epoxy/polyphenylene oxide, bismaleimide triazine (BT), thermount, cyanate ester, polyimide, and liquid crystal polymer.

In embodiments, the PCB may include a distribution pattern and a conductive via. The distribution pattern may be disposed on a top surface and a bottom surface of each of the plurality of base layers. The distribution pattern may include, for example, electrolytically deposited (ED) copper foil, rolled-annealed (RA) copper foil, stainless steel foil, aluminum foil, ultra-thin copper foils, sputtered copper, copper alloys, etc. The conductive via may electrically connect between the distribution patterns. The conductive via may be formed to pass through at least one of the plurality of base layers. In some embodiments, the conductive via may include copper, nickel, stainless steel, or beryllium copper.

In some embodiments, the lower package BPKG shown in FIG. 1A may be implemented as, but not limited to, a system-in-package (SiP).

The first die 100 may be attached to the first substrate 110 in a flip-chip manner. In some embodiments, the first die 100 may be attached to the first substrate 110 through solder balls 100b. In some embodiments, the first die 100 may include an integrated circuit (IC), a system-on-chip (SoC), an application processor (AP), a mobile AP, a chipset, or a set of chips. In some embodiment, the first die 100 may include a central processing unit (CPU), a graphics processing unit (GPU), and/or a modem. For example, the first die 100 may be implemented as, but not limited to, a modem die or a modem die supporting a wideband code division multiple access (WCDMA) communication scheme.

The second die 200 may be connected to the first substrate 110 by using a bonding wire 200w. The second die 200 may exchange signals with the first substrate 110 by using the bonding wire 200w. The second die 200 may be implemented as, but not limited to, a dynamic random access memory (DRAM) die or a pseudo static random access memory (SRAM) die. The pseudo SRAM may include an SRAM interface and a DRAM micro core. In some embodiments, the second die 200 may be attached to the first substrate 110 through a die attach material (not shown). In some embodiments, the die attach material may be, but not limited to, a film or a liquid epoxy adhesive.

The first die 100 and the second die 200 may be separated from each other in a horizontal direction D1 and may be attached to the first substrate 110 side by side.

On the first substrate 110, the vertical connection member 131 that electrically connects the first substrate 110 to the interposer substrate 130 may be disposed. The vertical connection member 131 may extend in the vertical direction D2 that is perpendicular to the horizontal direction D1. The vertical connection member 131 may extend perpendicularly from the top surface of the first substrate 110. The vertical connection member 131 may be a through mold via (TMV), a conductive pillar, or at least one conductive bump.

In some embodiments, the lower package BPKG may include a molding layer 140 that covers the first die 100, the second die 200, and the vertical connection member 131. More specifically, the molding layer 140 may cover a side surface and a top surface of the first die 100, a side surface and a top surface of the second die 200, and a side surface of the vertical connection member 131. In some embodiments, the molding layer 140 may be formed through a moldable underfill (MUF) process, and the molding layer 140 may cover the side surface and top and bottom surfaces of the first die 100.

The molding layer 140 may include an epoxy molding compound (EMC). However, without being limited thereto, the molding layer 140 may include various materials such as an epoxy-based material, a thermo-curable material, a thermoplastic material, an ultraviolet (UV) treatment material, etc.

The first substrate 110 may be a substrate for connecting the first die 100 and the second die 200 of the lower package BPKG and the third die 300 of the upper package TPKG to the external device. A plurality of first balls 111 contacting the external device may be attached under the first substrate 110. The PoP 10 according to an embodiment of the disclosure may be electrically connected to the external device through the plurality of first balls 111.

The upper package TPKG may include a second substrate 120, the third die 300 on the second substrate 120, and a plurality of ball pads 125 disposed on a surface of the second substrate 120. The plurality of ball pads 125 may include a package ball map 126 including cells forming a plurality of rows and a plurality of columns, in which one signal may be disposed in each cell.

The upper package TPKG may include at least one third die 300 attached onto the second substrate 120. The third die 300 may be attached onto a top surface 120a of the second substrate 120. In some embodiments, the upper package TPKG may include a plurality of third dies 300. The third die 300 may include a non-volatile memory device. The non-volatile memory device may include, but not limited to, at least any one of electrically erasable programmable read-only memory (EEPROM), flash memory, magnetic random access memory (MRAM), spin-transfer torque (STT)-MRAM, ferroelectric RAM (FeRAM), phase change RAM (PRAM), resistive RAM (RRAM), nanotube RRAM, polymer RAM (PoRAM), nano floating gate memory (NFGM), holographic memory, molecular electronics memory device, or insulator resistance change memory.

In other embodiments, the third die 300 may include volatile memory device. The volatile memory device may include, but not limited to, RAM, dynamic RAM (DRAM), or static RAM (SRAM).

The upper package TPKG may further include a memory controller 301 attached to the second substrate 120. The memory controller 301 may be attached onto the top surface 120a of the second substrate 120. The memory controller 301 may control an operation of the third die 300. When the third die 300 is a NAND flash die, the memory controller 301 may be a NAND flash controller. The NAND flash controller may provide an interface and a protocol for the third die 300. The NAND flash controller may provide a standard protocol for an interface such as parallel advanced technology attachment (PATA), serial advanced technology attachment (SATA), SCSI, or PCI express (PCIe). The NAND flash controller may perform wear leveling, garbage collection, bad block management, and an error correcting code (ECC) for the third die 300. Each of the third die 300 and the memory controller 301 may exchange signals with the second substrate 120 through a wire, a solder ball, or a bump.

At least one third die 300, the memory controller 301, and wires may be molded by a protective material 241. For example, the protective material may be, but not limited to, an EMC. The upper package TPKG may include the plurality of ball pads 125 disposed on a surface of the second substrate 120. The plurality of ball pads 125 may be disposed on a bottom surface 120b of the second substrate 120, in which the bottom surface 120b may be opposite to the top surface 120a of the second substrate 120 to which the third die 300 and the memory controller 301 are attached, in the vertical direction D2.

As stated above, by disposing the lower package BPKG having the first die 100 and the second die 200 mounted thereon under the upper package TPKG having the third die 300 mounted thereon, a horizontal area of the PoP 10 may be reduced without the lower package BPKG occupying a horizontal area that is separate from that occupied by the upper package TPKG. As the horizontal area of the PoP 10 is reduced, a mounting area of the PoP 10 on the system board may be reduced.

A plurality of second balls 121 for electrically connecting the second substrate 120 to the interposer substrate 130 may be attached under the plurality of ball pads 125. The plurality of second balls 121 may be attached to the plurality of ball lands 135 on a surface of the interposer substrate 130. That is, the plurality of second balls 121 may be simultaneously attached to the second substrate 120 and the interposer substrate 130, positions on the second substrate 120 to which the second ball 121 is attached may be the plurality of ball pads 125, and positions on the interposer substrate 130 to which the second ball 121 is attached may be the plurality of ball lands 135.

The PoP 10 according to an embodiment of the disclosure may include the interposer substrate 130 disposed between the lower package BPKG and the upper package TPKG. The interposer substrate 130 may be a PCB or an RDL.

The interposer substrate 130 may include the plurality of ball lands 135 disposed on a surface thereof. The plurality of second balls 121 may include a signal ball 121a for transmitting and receiving a data signal and/or a control signal to and from the third die 300, a power ball 121b for delivering a power signal to the third die 300, and a ground ball 121c for delivering a ground signal to the third die 300. The plurality of ball lands 135 may include a signal ball land 135a to which the signal ball 121a is attached, a power ball land 135b to which the power ball 121b is attached, and a ground ball land 135c to which the ground ball 121c is attached.

The plurality of ball lands 135 may be disposed on a surface of the interposer substrate 130 to correspond to the package ball map 126 of the upper package TPKG. At least some of or at least a portion of the plurality of ball lands 135 may overlap the first die 100 and the second die 200 of the lower package BPKG in the vertical direction D2. That is, the plurality of second balls 121 connecting the second substrate 120 to the interposer substrate 130 may be attached to positions on the interposer substrate 130 in which they overlap the first die 100 and the second die 200.

A package ball map may be of a tabular form for signals including input/output signals to/from a semiconductor package such that one signal may be placed in each cell of the package ball map, and the semiconductor package may have an input/output connection pad corresponding to the package ball map. In some cells of the package ball map, any signal may not be placed. Disposition of the package ball map and disposition of the input/output connection pad of the semiconductor package may be similar to each other, but the package ball map is in a tabular form for signals including input/output signals, and thus may not exactly match disposition of the input/output connection pad. For example, input/output connection pads of the semiconductor package for signals placed in one row or one column of the package ball map may also be formed to be disposed forming one row or one column, without being limited thereto. For example, a gap between or positions of the input/output connection pads of the semiconductor package may be changed slightly based on interference between signals, power supply, etc., and in this case, the input/output connection pads may be formed to be distributed without forming a row or a column for signals placed in some rows or some columns of the package ball map. However, as a whole, two signals placed in relatively close cells of the package ball map may correspond to two connection pads disposed close to each other in the semiconductor package, and two signals placed in relatively distant cells in the package ball map may correspond to two connection pads disposed far from each other in the semiconductor package.

The plurality of second balls 121 may be disposed on the interposer substrate 130 to correspond to the package ball map 126 arranged in the tabular form. For example, the plurality of second balls 121 connecting the second substrate 120 to the interposer substrate 130 may be disposed on the interposer substrate 130 to correspond to the package ball map 126. For example, the second ball 121 connected to other dies or the external device may be disposed on the interposer substrate 130 to correspond to the package ball map 126. In embodiments, the signal ball 121a for transmitting and receiving a data signal and/or a control signal to and from the third die 300 may be disposed on the interposer substrate 130 to correspond to the package ball map 126. In embodiments, the power ball 121b for delivering a power signal to the third die 300 may be disposed on the interposer substrate 130 to correspond to the package ball map 126. In embodiments, the ground ball 121c for delivering a ground signal to the third die 300 may be disposed on the interposer substrate 130 to correspond to the package ball map 126.

The PoP 10 according to an embodiment of the disclosure may include the interposer substrate 130 that may include the plurality of ball lands 135 that are positions to which the plurality of second balls 121 corresponding to the package ball map 126 and connecting the second substrate 120 to the interposer substrate 130 are attached. The plurality of ball lands 135 may be disposed on a surface of the interposer substrate 130. The plurality of second balls 121 may not need to be positioned not to overlap the first die 100 and the second die 200 so as to be adjacent to the vertical connection member 131 separated from the first die 100 and the second die 200 of the lower package BPKG in the horizontal direction D1. That is, the plurality of second balls 121 may also be attached to positions in which they overlap the first die 100 and the second die 200. That is, due to existence of the interposer substrate 130, positions to which the plurality of second balls 121 are attached may not be restricted by existence and/or positions of the first die 100 and the second die 200. As a result, the upper package TPKG may use a standard ball map configured suitably for the third die 300 included in the upper package TPKG, without a need to use a dedicated ball map separately configured based on the lower package BPKG including the first die 100 and the second die 200. The standard ball map that may be used in the disclosure may be, but not limited to, a standard ball map for NAND flash memory of the Joint Electron Device Engineering Council (JEDEC).

That is, the PoP 10 according to an embodiment of the disclosure may allow independent configuration of the ball map of the third die 300 and the ball map of the lower BPKG without one-to-one correspondence therebetween, thereby increasing the degree of freedom in adopting the third die 300.

Referring to FIGS. 1A and 1B together, in embodiments, a data signal and/or control signal 3SIG of the third die 300 of the upper package TPKG may be transmitted and received to and from the external device through the vertical connection member 131. More specifically, the data signal and/or control signal 3SIG of the third die 300 may be transmitted and received to and from the external device through the second substrate 120, the signal ball 121a, the interposer substrate 130, the vertical connection member 131, the first substrate 110, and a first ball 111a. The data signal and/or control signal 3SIG of the third die 300, transmitted and received through the vertical connection member 131, may not be electrically connected to the first die 100 and the second die 200 in the interposer substrate 130 and the lower package BPKG. That is, the data signal and/or control signal 3SIG of the third die 300 in the interposer substrate 130 and the lower package BPKG may be transmitted and received separately from the signals of the first die 100 and the signals of the second die 200.

In embodiments, a power signal 3PW of the third die 300 of the upper package TPKG may be delivered through the power ball 121b. More specifically, the power signal 3PW of the third die 300 may be delivered to the external device through the second substrate 120, the power ball 121b, the interposer substrate 130, the vertical connection member 131, the first substrate 110, and the first ball 111b. In some embodiments, the power signal 3PW of the third die 300 may be merged or combined with or split from a power signal of the lower package BPKG.

For example, referring to FIG. 1A, the power signal 3PW of the third die 300 may be delivered separately from a power signal 1PW of the first die 100. In this case, the power signal 1PW of the first die 100 may be delivered through another first ball (not shown) without passing through the first ball 111b to which the power signal 3PW of the third die 300 is delivered. In embodiments, likewise, the power signal 3PW of the third die 300 may be delivered after being merged or combined with a power signal (not shown) of the second die 200.

In other embodiments, referring to FIG. 1B, the power signal 3PW of the third die 300 may be delivered after being merged or combined with the power signal 1PW of the first die 100 in the first substrate 110. In this case, the power signal 3PW of the third die 300 and the power signal 1PW of the first die 100 may be merged or combined and delivered to the external device through the same first ball 111b. In embodiments, likewise, the power signal 3PW of the third die 300 may be delivered separately from a power signal (not shown) of the second die 200.

Referring to FIGS. 1A and 1B together, in embodiments, the ground signal 3GN of the third die 300 of the upper package TPKG may be delivered through the ground ball 121c. More specifically, the ground signal 3GN of the third die 300 may be delivered to the external device through the second substrate 120, the ground ball 121c, the interposer substrate 130, the vertical connection member 131, the first substrate 110, and the first ball 111c. In some embodiments, the ground signal 3GN of the third die 300 may be merged or combined with the ground signal of the lower package BPKG. For example, referring to FIG. 1A, the ground signal 3GN of the third die 300 may be delivered after being merged or combined with the ground signal 2GN of the second die 200. In this case, the ground signal 3GN of the third die 300 and the ground signal 2GN of the second die 200 may be merged or combined with each other and delivered to the external device through the first ball 111c. In embodiments, likewise, the ground signal 3GN of the third die 300 may be delivered after merged or combined with a ground signal (not shown) of the first die 100.

In embodiments, the first die 100 and the second die 200 attached to the first substrate 110 may be supplied with an operating voltage and/or a ground voltage through the plurality of first balls 111 and the first substrate. That is, the first die 100 and the second die 200 may be pin-out through the plurality of first balls 111.

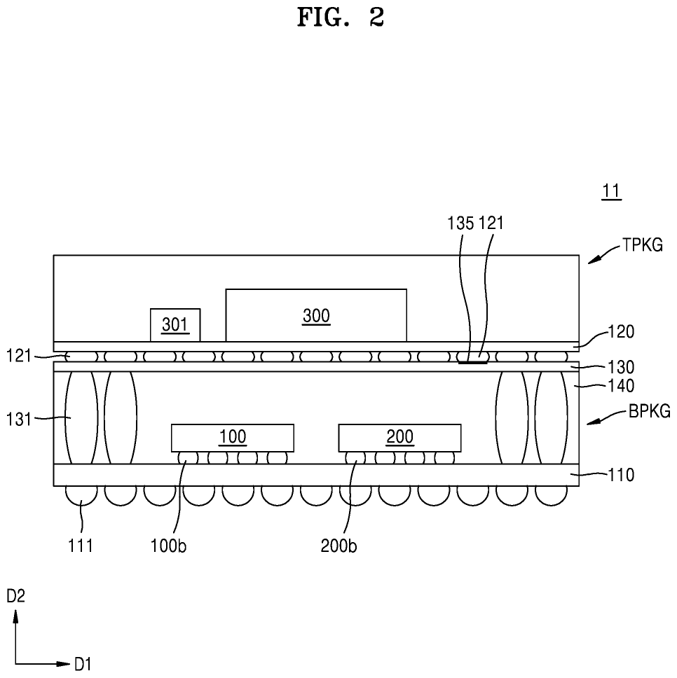

FIGS. 2 to 5 show other examples of the PoP 10 according to an embodiment of the disclosure shown in FIG. 1A. Hereinbelow, a description will be mainly made on aspects that are different from that described with reference to FIG. 1A.

Referring to FIG. 2, a PoP 11 according to an embodiment of the disclosure may include the lower package BPKG, the upper package TPKG, and the interposer substrate 130 disposed between the lower package BPKG and the upper package TPKG.

The lower package BPKG may include the first substrate 110, the first die 100 and the second die 200 disposed side by side in the horizontal direction D1 on the first substrate 110, the vertical connection member 131 electrically connecting the first substrate 110 to the interposer substrate 130 between the first substrate 110 and the interposer substrate 130, and the molding layer 140 that covers the first die 100, the second die 200, and the vertical connection member 131.

More specifically, the first die 100 and the second die 200 may be attached to a top surface of the first substrate 110. The first die 100 may be attached to the first substrate 110 in a flip-chip manner. The second die 200 may be attached to the first substrate 110 in the flip-chip manner like the first die 100, unlike shown in FIG. 1A. In embodiments, the second die 200 may be attached to the first substrate 110 through solder balls 200b. The first die 100 and the second die 200 may be separated from each other in the horizontal direction D1 and may be attached to the first substrate 110 side by side.

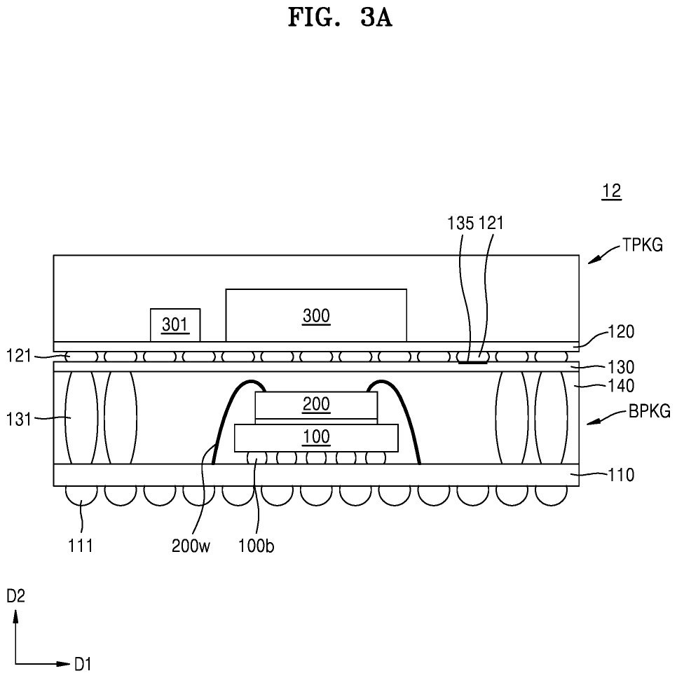

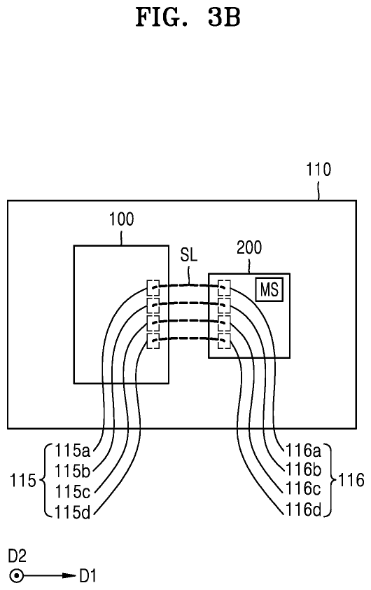

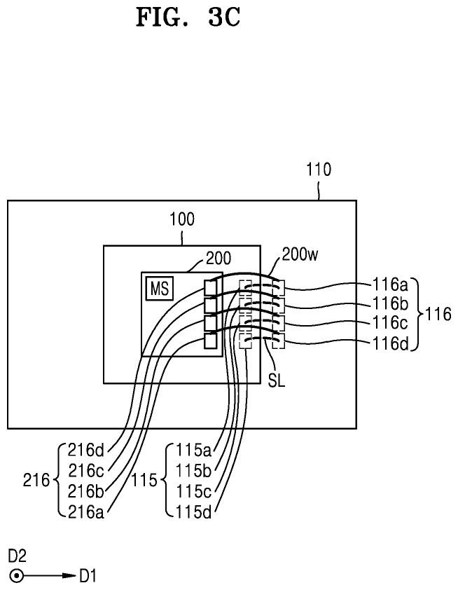

Referring to FIG. 3A, a PoP 12 according to an embodiment of the disclosure may include the lower package BPKG, the upper package TPKG, and the interposer substrate 130 disposed between the lower package BPKG and the upper package TPKG.

The lower package BPKG may include the first die 100 and the second die 200 attached to the top surface of the first substrate 110, and the second die 200 may be stacked on the first die 100. The second die 200 may be stacked on the first die 100 in the vertical direction D2. The second die 200 may be stacked on the first die 100. The first die 100 may be attached to the first substrate 110 in the flip-chip manner. The second die 200 may be connected to the first substrate 110 by using the bonding wire 200w.

In embodiments, the first die 100 and the second die 200 may be connected through signal lines (not shown) implemented inside the first substrate 110. Thus, the first die 100 and the second die 200 may exchange signals through the signal lines implemented inside the first substrate 110. For example, the first die 100 and the second die 200 may exchange a data signal and/or control signal, a power signal, a ground signal, etc., through the signal lines (not shown) implemented inside the first substrate 110.

In embodiments, the operating voltage and/or the ground voltage of the first die 100 may be supplied to the first die 100 through the plurality of first balls 111. Similarly, the operating voltage and/or the ground voltage of the second die 200 may be supplied to the second die 200 through the plurality of first balls 111.

FIGS. 3B and 3C are schematic plane views of some components of PoPs according to embodiments of the disclosure shown in FIGS. 1A and 3A.

Referring to FIGS. 3A and 3C, the first substrate 110 may include, on a surface thereof, a plurality of signal pads electrically connected to the first die 100 and the second die 200. The plurality of signal pads may include a first signal pad 115 and a second signal pad 116. —The first die 100 and the second die 200 may include, on surfaces thereof, a first die pad (not shown) and a second die pad 216 for connection to the first signal pad 115 and the second signal pad 116. The first signal pad 115 may be connected to the first die 100 and the second signal pad 116 may be connected to the second die 200. More specifically, the first signal pad 115 may be connected to the first die pad of the first die 100, and the second signal pad 116 may be connected to the second die pad 216 of the second die 200. The first signal pad 115 and the second signal pad 116 may transmit and receive data signals between the first die 100 and the second die 200. The first signal pad 115 and the second signal pad 116 may transmit and receive data signals between the first die 100 and the second die 200 through signal lines SL implemented inside the first substrate 110.

FIG. 3B shows positions of the first signal pad 115 and the second signal pad 116 when the first die 100 and the second die 200 are attached onto the first substrate 110 side by side as shown in FIG. 1A. Although not shown, the first die 100 may include a first die pad at a position overlapping the first signal pad 115, and the second die 200 may include a second die pad at a position overlapping the second signal pad 116. When the first die 100 and the second die 200 are placed side by side, the first signal pad 115 and the second signal pad 116 are disposed to face each other or are disposed across from each other such that the signal lines SL for transmitting and receiving data signals maintain the shortest distance without intersecting each other. —In embodiments, as shown, the first signal pads 115 and the second signal pads 116 facing each other may be connected to the signal lines SL to transmit and receive a data signal. That is, a first signal pad 115a and a second signal pad 116a, a first signal pad 115b and a second signal pad 116b, a first signal pad 115c and a second signal pad 116c, and a first signal pad 115d and a second signal pad 116d may be connected by the signal lines SL to transmit and receive data signals. The first die 100 and the second die 200, and the first die pad and the second die pad may also be disposed to transmit and receive data signals through the first signal pad 115 and the second signal pad 116.

FIG. 3C shows the first signal pad 115, the second signal pad 116, and the second die pad 216 when the second die 200 is stacked on the first die 100 in the vertical direction D2 as shown in FIG. 3A. In order for the signal lines SL transmitting and receiving data signals to maintain the shortest distance without intersecting one another when the second die 200 is placed on the first die 100, the second die 200 may be placed on the first die 100 by rotating 180° with respect to the vertical direction D2 as is shown. That is, the positions of the second die pads 216 on the surface of the second die 200 are effectively rotated 180° with respect to the vertical direction D2, when compared to the positions of the second die pads in FIG. 3B. In embodiments, as shown, the first signal pads 115 and the second signal pads 116 facing each other may be connected to the signal lines SL to transmit and receive a data signal. The second signal pads 116 may be connected to the second die 200, i.e., the second die pads 216, by the bonding wire 200w. In this case, the second die pads 216 may be rotated 180° when compared to the orientation of the second die pads 216 in FIG. 3B, such that the second signal pad 116a may be connected to a second die pad 216d, the second signal pad 116b may be connected to a second die pad 216c, the second signal pad 116c may be connected to a second die pad 216b, and the second signal pad 116d may be connected to a second die pad 216a. That is, the order is reversed from that shown in FIG. 3B, such that any one of the orders of the data signals of the second die 200 transmitted and received through the second die pad 216 may be swapped.

The second die 200 may include a mode swap pad MS on a surface thereof. The mode swap pad MS may transmit and receive a mode swap signal that swaps orders of data signals of the second die 200 transmitted and received through the second die pad 216. As shown in FIG. 3C, when the positions of the second die pad 216 are rotated 180° with respect to the positions of the second signal pad 116, i.e., rotated 180° with respect to the orientation of the second die pad of FIG. 3B, any one of the orders of the data signals transmitted and received through the second die pad 216 may be swapped.

In some embodiments, when data signals transmitted and received through the second die pad 216 are exchanged, signals previously transmitted and received through the second die pad 216a may be transmitted and received through the second die pad 216d, signals previously transmitted and received through the second die pad 216b may be transmitted and received through the second die pad 216c, signals previously transmitted and received through the second die pad 216c may be transmitted and received through the second die pad 216b, and signals previously transmitted and received through the second die pad 216d may be transmitted and received through the second die pad 216a.

In a corresponding embodiment, the second die pad 216a and the second signal pad 116d, the second die pad 216b and the second signal pad 116c, the second die pad 216c and the second signal pad 116b, and the second die pad 216d and the second signal pad 116a are connected by the bonding wire 200w, such that when the order of the data signal transmitted and received through the second die pad 216 is reversed, the data signal previously transmitted and received through the second die pad 216a may be transmitted and received through the second signal pad 116a, a signal previously through the existing second die pad 216b may be transmitted and received through the second signal pad 116b, a signal previously through the second die pad 216c may be transmitted and received through the second signal pad 116c, and a signal previously through the second die pad 216d may be transmitted and received through the second signal pad 116d. As stated above, the first signal pads 215 and the second signal pads 116 may be connected by the signal lines SL to transmit and receive data signals, and as a result, data signals of the second die 200 transmitted and received through the second die pad 216 may be identically exchanged through the second signal pad 116 and the first signal pad 115.

Due to the mode swap pad MS for transmitting and receiving a mode swap signal, various types of die arrangement with one type of the first substrate 110, the first die 100, and the second die 200 may be possible. For example, the first die 100 and the second die 200 may be disposed side by side in the horizontal direction D1 on the first substrate 110 of one type, and the second die 200 may be stacked on the first die 100 on the first substrate 110 in the vertical direction D2. Even when the first die 100 and the second die 200 are arranged differently, data exchange between the first die 100 and the second die 200 may be identically performed.

While the mode swap pad MS for swapping the orders of the data signals of the second die 200 is included on a surface of the second die in the current embodiment, the mode swap pad MS for swapping the orders of the data signals of the first die 100 may be included on a surface of the first die 100 in another embodiment, without being limited thereto.

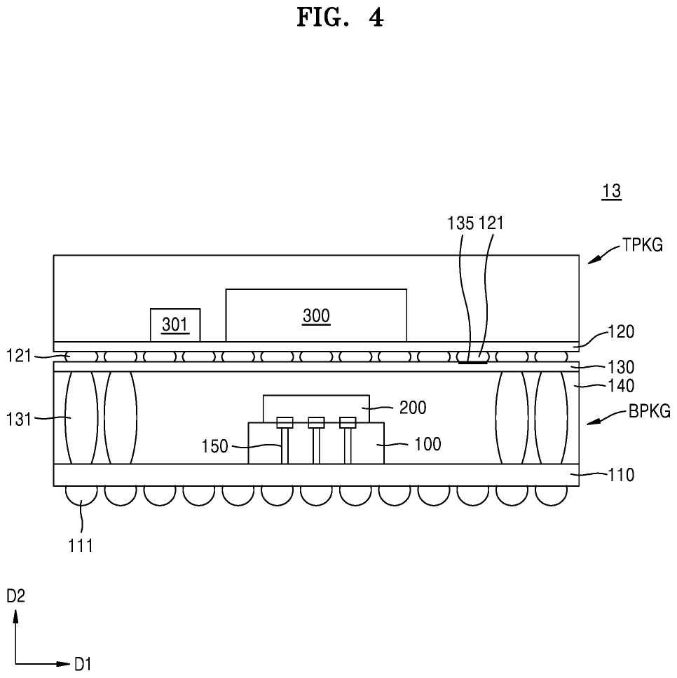

Referring to FIG. 4, a PoP 13 according to an embodiment of the disclosure may include the lower package BPKG, the upper package TPKG, and the interposer substrate 130 disposed between the lower package BPKG and the upper package TPKG. The lower package BPKG may include the first die 100 and the second die 200 attached to the top surface of the first substrate 110, and the second die 200 may be stacked on the first die 100. The first die 100 and the second die 200 may be connected to each other through a through silicon via (TSV) 150. The first die 100 and the second die 200 may be connected to the first substrate 110 through the TSV 150. When the first die 100 and the second die 200 are connected to the first substrate 110 through the TSV 150, the size of the lower package BPKG may be reduced.

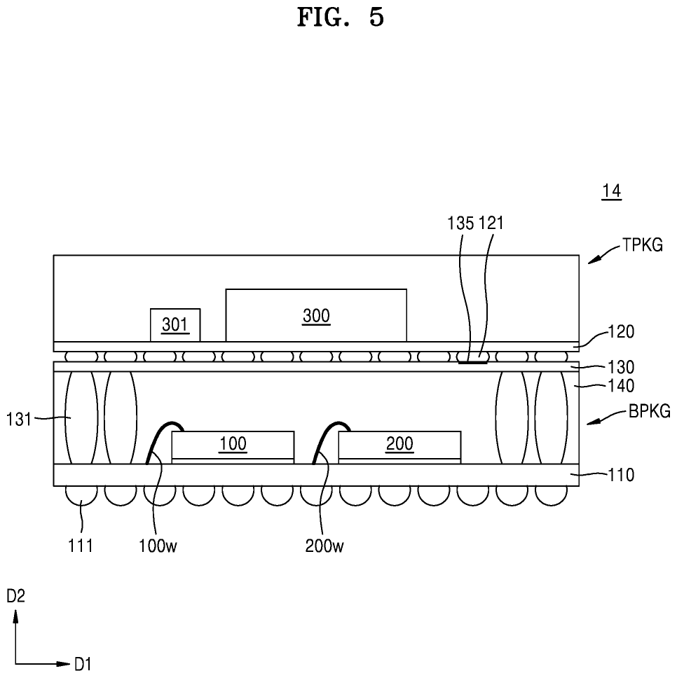

Referring to FIG. 5, a PoP 14 according to an embodiment of the disclosure may include the lower package BPKG, the upper package TPKG, and the interposer substrate 130 disposed between the lower package BPKG and the upper package TPKG. The lower package BPKG may include the first die 100 and the second die 200 attached to the top surface of the first substrate 110, and the first die 100 and the second die 200 may be connected to the first substrate 110 by using bonding wires 100w and 200w. The first die 100 and the second die 200 may be attached to the first substrate 110 side by side in the horizontal direction D1.

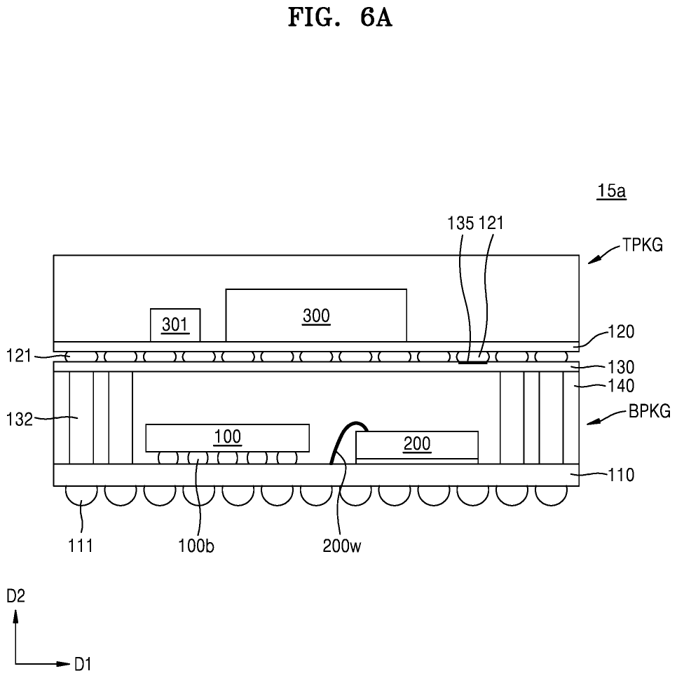

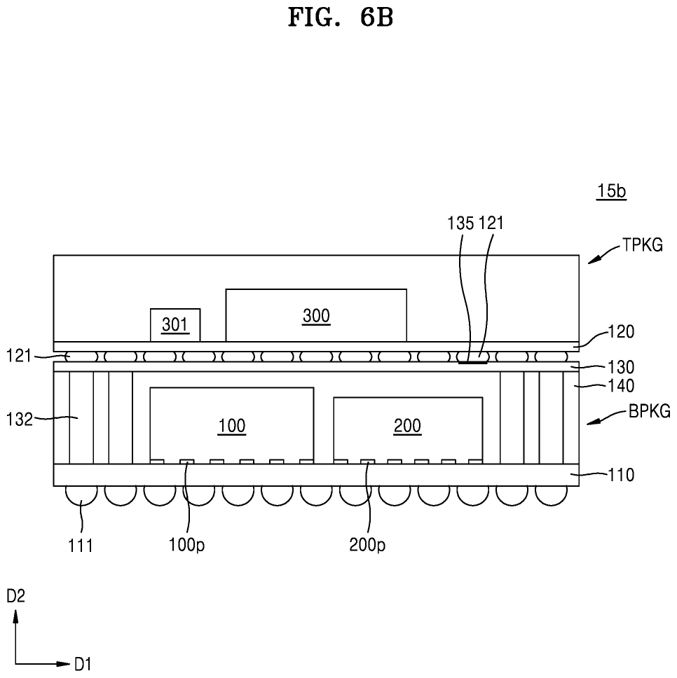

FIGS. 6A to 10 show other embodiments of PoPs 10 to 14 according to embodiments of the disclosure shown in FIGS. 1 to 5. Other than including a post 132 electrically connecting the first substrate 110 to the interposer substrate 130, instead of the vertical connection member 131, a description is similar to that made with reference to FIGS. 1A to 5. The post 132 may be a copper (Cu) post, without being limited thereto.

Referring to FIGS. 6A and 6B, PoPs 15a and 15b may include the lower package BPKG, the upper package TPKG, and the interposer substrate 130 disposed between the lower package BPKG and the upper package TPKG. The lower package BPKG may include the first substrate 110, the first die 100 and the second die 200 disposed side by side in the horizontal direction D1 on the first substrate 110, the post 132 electrically connecting the first substrate 110 to the interposer substrate 130 between the first substrate 110 and the interposer substrate 130, and a molding layer 140 that covers the first die 100, the second die 200, and the post 132.

Referring to FIG. 6A, the first die 100 and the second die 200 may be attached to the top surface of the first substrate 110 of the PoP 15a. The first die 100 may be attached to the first substrate 110 in the flip-chip manner. In embodiments, the first die 100 may be attached to the first substrate 110 through the solder balls 100b. The second die 200 may be connected to the first substrate 110 by using the bonding wire 200w. The first die 100 and the second die 200 may be separated from each other and may be attached to the first substrate 110 side by side in the horizontal direction D1. In embodiments, the first substrate 110 may be an RDL, and after the first substrate 110 is formed through a redistribution process, the first die 100 and the second die 200 may be attached to the first substrate 110.

Referring to FIG. 6B, unlike shown in FIG. 6A, the first die 100 and the second die 200 of the PoP 15b may be attached to the first substrate 110 through pads 100p and 200p. In embodiments, after the first die 100 and the second die 200 are attached to a support substrate (not shown), the support substrate may be turned over to form the first substrate 110 through the redistribution process.

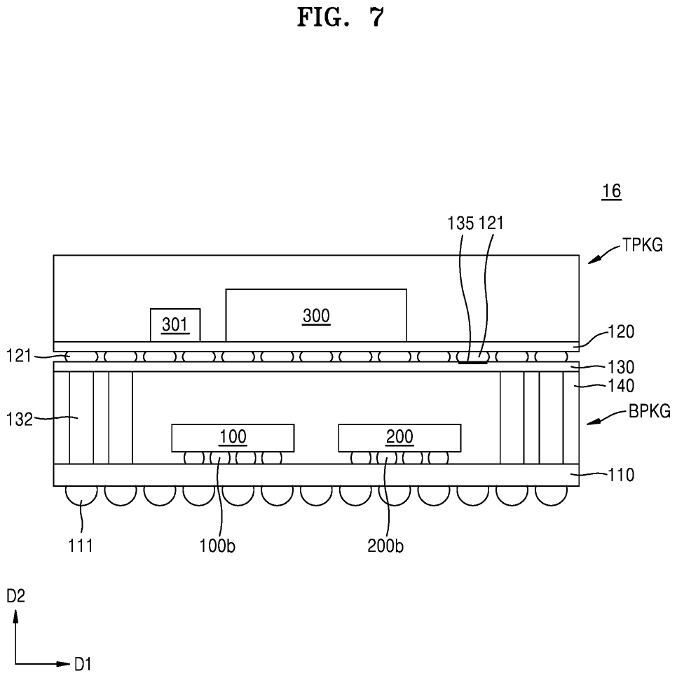

Referring to FIGS. 7 through 10, PoPs 16 to 19 may include the lower package BPKG, the upper package TPKG, and the interposer substrate 130 disposed between the lower package BPKG and the upper package TPKG. The lower package BPKG may include the first substrate 110, the first die 100 and the second die 200 stacked on the first substrate 110, the post 132 electrically connecting the first substrate 110 to the interposer substrate 130 between the first substrate 110 and the interposer substrate 130, and the molding layer 140 covering the first die 100, the second die 200, and the post 132.

Referring to FIG. 7, the first die 100 and the second die 200 may be attached to the first substrate 110 in the flip-chip manner. In embodiments, the first die 100 and the second die 200 may be attached to the first substrate 110 through the solder balls 200b. The first die 100 and the second die 200 may be separated from each other in the horizontal direction D1 and may be attached to the first substrate 110 side by side.

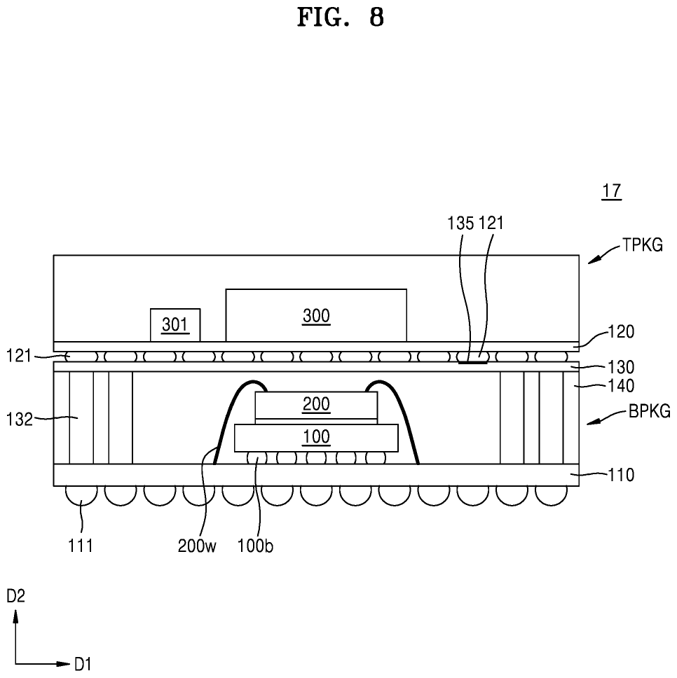

Referring to FIG. 8, the second die 200 may be stacked on the first die 100. The first die 100 may be attached to the first substrate 110 in the flip-chip manner. The second die 200 may be connected to the first substrate 110 by using the bonding wire 200w.

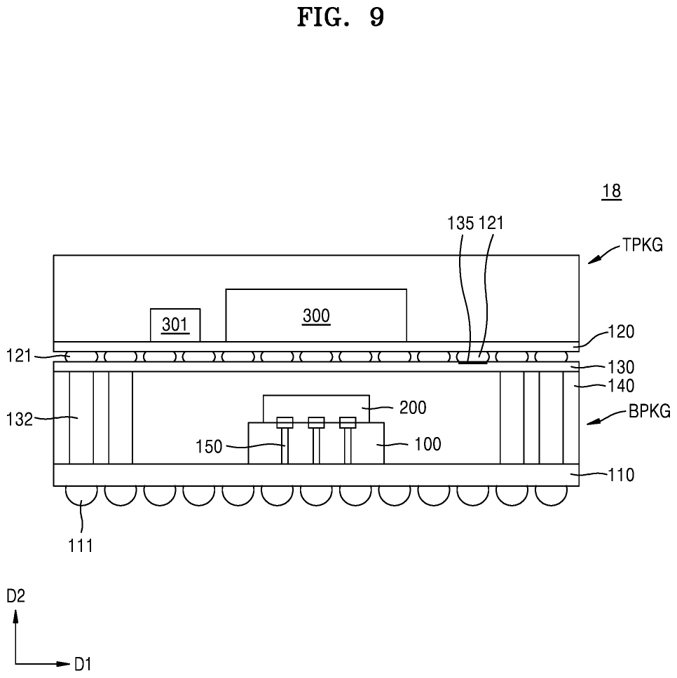

Referring to FIG. 9, the second die 200 may be stacked on the first die 100. The first die 100 and the second die 200 may be connected to each other through the TSV 150. The first die 100 and the second die 200 may be connected to the first substrate 110 through the TSV 150.

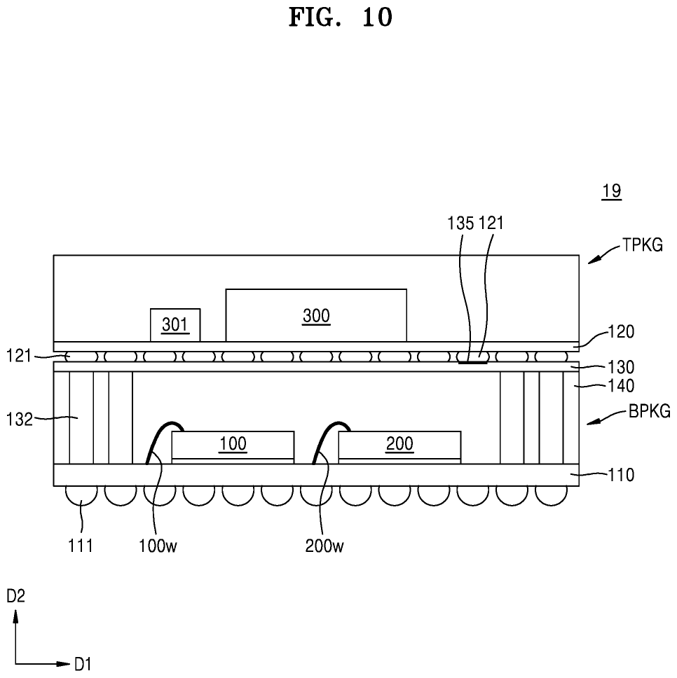

Referring to FIG. 10, the first die 100 and the second die 200 may be connected to the first substrate 110 by using the bonding wires 100w and 200w. The first die 100 and the second die 200 may be attached to the first substrate 110 side by side in the horizontal direction D1.

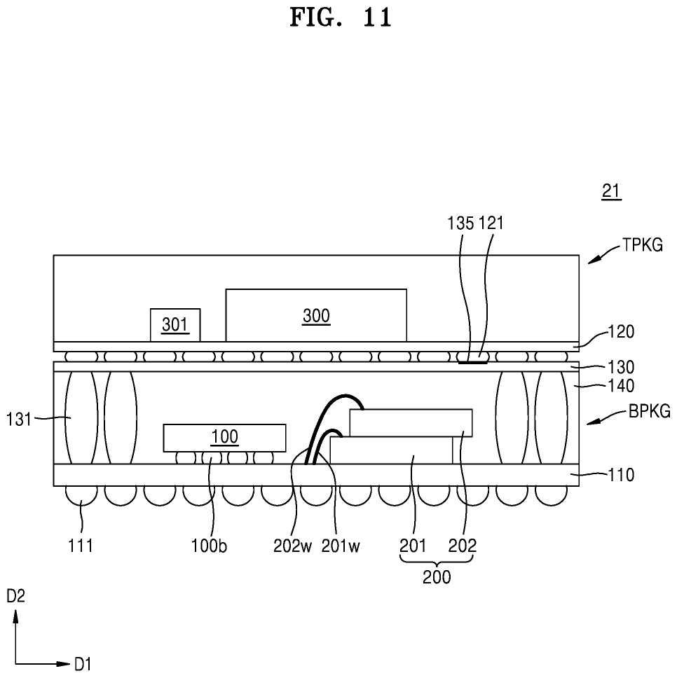

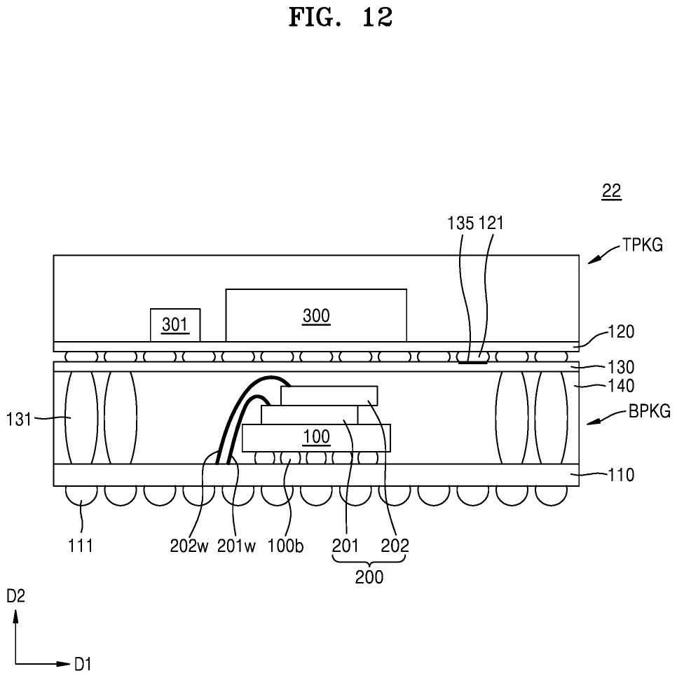

FIGS. 11 and 12 are cross-sectional views of PoPs according to embodiments of the disclosure. PoPs 21 and 22 shown in FIGS. 11 and 12 may be other examples of the PoPs 10 to 14 according to embodiments of the disclosure shown in FIGS. 1 to 5. Other than the second die 200 including a first sub die 201 and a second sub die 202, the PoPs 21 and 22 are similar as described with reference to FIGS. 1A to 5.

Referring to FIGS. 11 and 12, the PoPs 21 and 22 may include the lower package BPKG, the upper package TPKG, and the interposer substrate 130 disposed between the lower package BPKG and the upper package TPKG. The lower package BPKG may include the first substrate 110, the first die 100 disposed on the first substrate 110, the second die 200 including the first sub die 201 and the second sub die 202 stacked on each other, the vertical connection member 131 electrically connecting the first substrate 110 to the interposer substrate 130 between the first substrate 110 and the interposer substrate 130, and the molding layer 140 that covers the first die 100, the second die 200, and the vertical connection member 131. While an example where the PoPs 21 and 22 include the vertical connection member 131 is shown, this is merely the example and the post 132 electrically connecting the first substrate 110 to the interposer substrate 130, in place of the vertical connection member 131, may be included.

The second die 200 may include the first sub die 201 and the second sub die 202 that are stacked on each other. The first sub die 201 may be disposed on the first substrate 110, and the second sub die 202 may be disposed on the first sub die 201. That is, the first sub die 201 and the second sub die 202 may be stacked in the vertical direction D2 and disposed on the first substrate 110.

The first sub die 201 and the second sub die 202 may be connected to the first substrate 110 by using bonding wires 201w and 202w. The first sub die 201 and the second sub die 202 may exchange signals with the first substrate 110 by using the bonding wire 200w. The first sub die 201 and the second sub die 202 may be implemented as, but not limited to, DRAM.

As the second die 200 includes the first sub die 201 and the second sub die 202, the second die 200 may have an increased density. More specifically, as the second die 200 includes the first sub die 201 and the second sub die 202, the density of the second die 200 may increase, or as the memory bandwidth of the second die 200 increases, the density of the second die 200 may increase.

For example, in case of connection to the substrate using the bonding wire by stacking the two identical sub dies 201 and 202, the memory bandwidth may be doubled, thus doubling data processing speed and accordingly doubling the memory capacity. Alternatively, the memory capacity may be doubled while maintaining the memory bandwidth.

Herein, a description will be described of, as an example, a case where the second die 200 includes the two sub dies 201 and 202, but the technical spirit of the disclosure may include a plurality of sub dies without being limited thereto. In this case, the memory bandwidth and capacity of the second die 200 may increase corresponding to the type and number of sub dies.

Referring to FIG. 11, the first die 100 and the second die 200 may be separated from each other in the horizontal direction D1 and may be attached to the first substrate 110 side by side. That is, the first die 100 may be separated from the first sub die 201 and the second sub die 202 stacked in the vertical direction D2 and attached to the first substrate 110 and may be attached to the first substrate 110 side by side with the first sub die 201 and the second sub die 202. The first die 100 may be attached to the first substrate 110 in the flip-chip manner, and the first sub die 201 and the second sub die 202 may be attached to the first substrate 110 by using the bonding wires 201w and 202w.

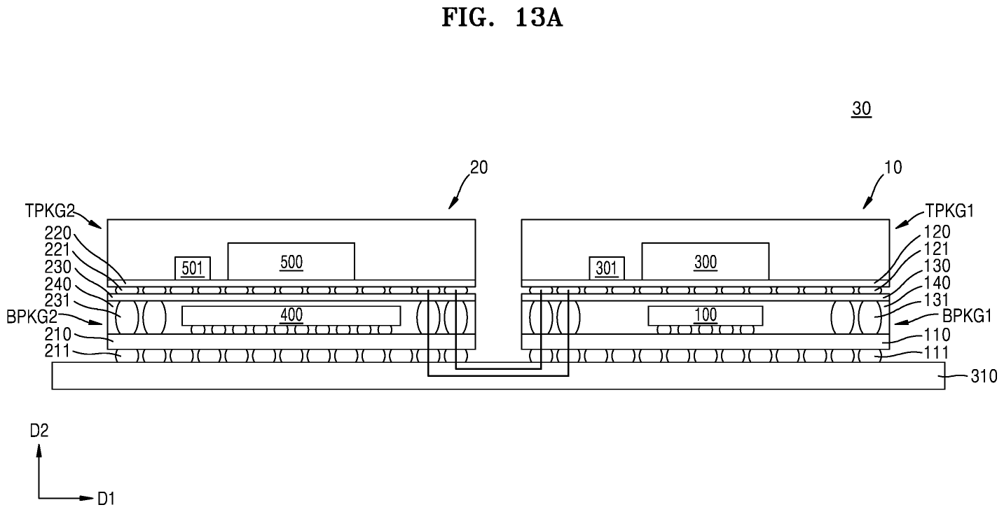

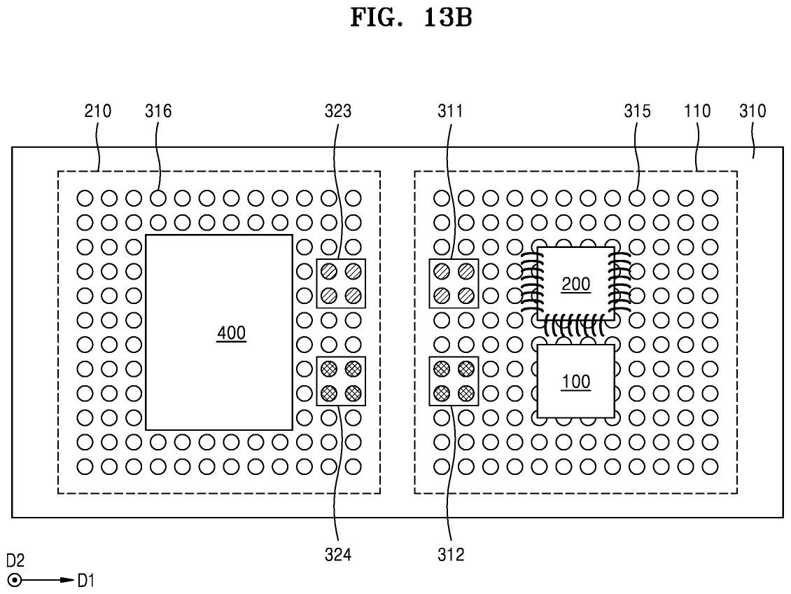

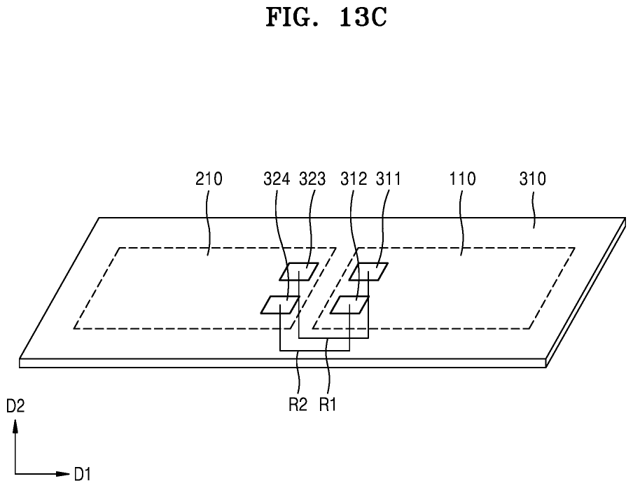

Referring to FIG. 12, the PoP 22 may include the first die 100 and the second die 200 attached to the top surface of the first substrate 110, and the second die 200 may be stacked on the first die 100. That is, on the first die 100, the first sub die 201 and the second sub die 202 stacked in the vertical direction D2 and attached to the first substrate 110 may be stacked. The first die 100 may be attached to the first substrate 110 in the flip-chip manner, and the first sub die 201 and the second sub die 202 may be attached to the first substrate 110 by using the bonding wires 201w and 202w. FIGS. 13A through 13C are views related to a package module according to an embodiment of the disclosure. FIG. 13A is a cross-sectional view of a package module according to an embodiment of the disclosure. FIG. 13B is a schematic plane view of some components of a package module according to embodiments of the disclosure shown in FIG. 13A. FIG. 13C is a perspective view schematically showing some components including a system board of a package module according to an embodiment of the disclosure shown in FIG. 13A.

Referring to FIGS. 13A and 13B together, a package module 30 according to an embodiment of the disclosure may include a system board 310 and a first package 10 and a second package 20 attached to the system board 310, in which the first package 10 may include a first lower package BPKG1, a first upper package TPKG1 disposed on the first lower package BPKG1, and a first interposer substrate 130 disposed between the first lower package BPKG1 and the first upper package TPKG1, and the second package 20 may include a second lower package BPKG2, a second upper package TPKG2 disposed on the second lower package BPKG2, and a second interposer substrate 230 disposed between the second lower package BPK2 and the second upper package TPKG2.

The first lower package BPKG1 may include the first substrate 110, the first die 100 and the second die 200 disposed on the first substrate 110, and the vertical connection member 131 electrically connecting the first substrate 110 to the interposer substrate 130 between the first substrate 110 and the interposer substrate 130, and the first upper package TPKG1 may include the second substrate 120 and the third die 300 on the second substrate 120. According to an embodiment, the first package 10 may be implemented as a PoP. A cross-sectional view of the first package 10 shown in FIG. 13A may be a cross-sectional view of the PoP 10 shown in FIG. 1A, cut in a different direction. The first package 10 included in the package module 30 shown in FIG. 13A may be, but not limited to the PoP 10 shown in FIG. 1A. For example, the first package 10 included in the package module 30 may be any one of the PoPs 10 to 19 as shown in FIGS. 1A to 10.

In embodiments, the first lower package BPKG1 may be a SiP including a modem ide and a DRAM die. That is, the first die 100 may be implemented as, but not limited to a modem die or a modem die supporting a WCDMA communication scheme. The second die 200 may be implemented as, but not limited to, a DRAM die or a pseudo SRAM die.

In embodiments, the first die 100 may be attached to the first substrate 110 in the flip-chip manner. In embodiments, the first die 100 may be attached to the first substrate 110 through the solder balls. The second die 200 may be connected to the first substrate 110 by using the bonding wire. The second die 200 may exchange signals with the first substrate 110 by using the bonding wire. The first die 100 and the second die 200 may be separated from each other in the horizontal direction D1 and may be attached to the first substrate 110 side by side. In other embodiments, the first die 100 and the second die 200 may be attached to the first substrate 110 in the flip-chip manner, or may be connected to the first substrate 110 by using the bonding wire. In other embodiments, the second die 200 may be stacked on the first die 100.

In embodiments, the first vertical connection member 131 electrically connecting the first substrate 110 to the first interposer substrate 130 may be disposed on the first substrate 110. A description of the vertical connection member 131 may be similar to the description made with reference to FIG. 1A.

In embodiments, the first lower package BPKG1 may include a first molding layer 140 that covers the first die 100, the second die 200, and the vertical connection member 131. A description of the first molding layer 140 may be similar to the description made with reference to FIG. 1A.

In embodiments, the first substrate 110 may be a substrate for connecting the first die 100 and the second die 200 of the first lower package BPKG1 and the third die 300 of the first upper package TPKG1 to the external device. In some embodiments, the first substrate 110 may be a PCB or a redistribution substrate. The plurality of first balls 111 contacting the external device may be attached under the first substrate 110. The PoP 10 according to an embodiment of the disclosure may be electrically connected to the external device through the plurality of first balls 111. In embodiments, the plurality of first balls 111 may be intended to electrically connect the first package 10 to the system board 310.

In embodiments, the first upper package TPKG1 may further include a non-volatile memory die and a memory controller controlling an operation of the non-volatile memory die. That is, the third die 300 may include a non-volatile memory die. Alternatively, the third die 300 may include NAND flash, NOR flash, ROM, XPoint memory, FRAM, etc. In embodiments, the first upper package TPKG1 may further include the memory controller 301 attached to the second substrate 120 and controlling an operation of the third die 300.

In embodiments, the first interposer substrate 130 and the second substrate 120 may be electrically connected by the plurality of second balls 121 which may be attached to a plurality of ball lands on the first interposer substrate 130 and a plurality of ball pads on the second substrate 120. The plurality of ball lands on the first interposer substrate 130 and the plurality of ball pads on the second substrate 120 may correspond to a package ball map including cells forming a plurality of rows and a plurality of columns, in which one signal may be placed in each cell.

By disposing the first lower package BPKG1 having the first die 100 and the second die 200 mounted thereon under the first upper package TPKG1 having the third die 300 mounted thereon, a horizontal area of the first package 10 may be reduced without the first lower package BPKG1 occupying a separate horizontal area. As the horizontal area of the first package 10 is reduced, a mounting area of the first package 10 on the system board 310 may be reduced. As a result, the size of the system board 310 may be reduced and thus the total size of the package module 30 may be reduced. Size reduction of the system board 310 and the package module 30 may lead to corresponding cost reduction.

The second lower package BPKG2 may include a third substrate 210, a fourth die 400 stacked on the third substrate 210, and a second vertical connection member 231 electrically connecting the third substrate 210 to the second interposer substrate 230, and the second upper package TPKG2 may include a fourth substrate 220 and a fifth die 500 on the fourth substrate 220. According to an embodiment, the second package 20 may be implemented as a PoP.

In embodiments, the second lower package BPKG2 may be an AP SoC. That is, the fourth die 400 may include, but not limited to, an AP die. According to embodiments, the fourth die 400 may be attached to the third substrate 210 in the flip-chip manner. According to another embodiment, the fourth die 400 may be attached to the third substrate 210 using a die attach material. The fourth die 400 may exchange signals with the third substrate 210 by using the bonding wire.

In embodiments, the second upper package TPKG2 may further include a memory die and a memory controller controlling an operation of the memory die. The fifth die 500 may include, but not limited to, a volatile memory die. For example, the fifth die 500 may include a DRAM die, an XPoint memory die, an MRAM die, an FRAM die, a PRAM die, etc.

The second supper packager TPKG2 may further include a memory controller 501 controlling an operation of the fifth die 500. According to an embodiment, the fifth die 500 may be attached to the fourth substrate 220 in the flip-chip manner. According to another embodiment, the fifth die 500 may be attached to the fourth substrate 220 using a die attach material. In this case, the fifth die 500 may exchange signals with the fourth substrate 220 by using the bonding wire.

In embodiments, the second vertical connection member 231 electrically connecting the third substrate 210 to the second interposer substrate 230 may be disposed on the third substrate 210. In embodiments, the second lower package BPKG2 may include a second molding layer 240 that covers the third die 300 and the second vertical connection member 231.

In embodiments, the third substrate 210 may include a third ball 211 contacting the external device thereunder. The third ball 211 may be intended to electrically connect the third substrate 210, the second lower package BPKG2, the second upper package TPKG2, or the second package 20 according to an embodiment of the disclosure to the external device. In embodiments, the third ball 211 may be intended to electrically connect the second package 20 to the system board 310.

In embodiments, the second interposer substrate 230 and the fourth substrate 220 may be electrically connected by a plurality of fourth balls 221 which may be attached to a plurality of ball lands on the second interposer substrate 230 and a plurality of ball pads on the fourth substrate 220. The plurality of ball lands on the second interposer substrate 230 and the plurality of ball pads on the fourth substrate 220 may correspond to a package ball map including cells forming a plurality of rows and a plurality of columns, in which one signal may be placed in each cell.

The first interposer substrate 130 and the second interposer substrate 230 may be a PCB or an RDL.

Referring to FIG. 13A, in a package module according to an embodiment of the disclosure, the first package 10 and the second package 20 may be disposed side by side on the same surface of the system board 310 in the horizontal direction D1.

Referring to FIGS. 13B and 13C, in embodiments, the system board 310 may include, on a surface thereof, a plurality of pads which may include a plurality of first pads 315 for connection to the first substrate 110 and a plurality of second pads 316 for connection to the third substrate 210. The system board 310 may include a first zone 311 in which some of the plurality of first pads 315 are disposed, a second zone 312 in which some others of the plurality of first pads 315 are disposed, a third zone 323 in which some of the plurality of second pads 316 are disposed, and a fourth zone 324 in which some others of the plurality of second pads 316 are disposed.

In some embodiments, the first zone 311 may be electrically connected to the first vertical connection member 131 that transmits and receives a data signal and/or control signal of the third die 300, through the first substrate 110, and the third zone 323 may be electrically connected to the second vertical connection member 231 that transmits and receives a data signal and/or control signal of the fifth die 500, through the third substrate 210.

Referring to FIGS. 13A to 13C, in a package module according to an embodiment of the disclosure, the plurality of first pads 315 and the plurality of second pads 316, and the first zone 311 to the fourth zone 324 may be formed on the same surface of the system board 310.

Referring to FIG. 13B, the plurality of first pads 315 for connection to the first substrate 110 may overlap the first substrate 110 in the vertical direction D2. To indicate this, the first substrate 110 overlapping the plurality of first pads 315 is shown as dashed lines. Likewise, the plurality of second pads 316 for connection to the third substrate 210 may overlap the third substrate 210 in the vertical direction D2. To indicate this, the third substrate 210 overlapping the plurality of second pads 316 is shown as dashed lines.

Referring to FIG. 13C, the first zone 311 and the third zone 323 are connected by first routing R1 in the system board 310, the second zone 312 and the fourth zone 324 are connected by second routing R2 in the system board 310, and the first routing R1 and the second routing R2 may not intersect each other.

In embodiments, a distance between the first zone 311 and the third zone 323 may be shorter than a distance between the first zone 311 and the fourth zone 324, and a distance between the second zone 312 and the fourth zone 324 may be shorter than a distance between the second zone 312 and the third zone 323. That is, the first zone 311 to the fourth zone 324 may be disposed such that the first zone 311 and the third zone 323 are connected by the shortest distance, and the second zone 312 and the fourth zone 324 are connected by the shortest distance.

Referring to FIGS. 13A to 13C, in some embodiments where the first package 10 and the second package 20 are disposed on the same surface of the system board 310, the first zone 311 and the second zone 312 may be disposed on a side where the first substrate 110 is oriented toward the third substrate 210, and the third zone 323 and the fourth zone 324 may be disposed on a side where the third substrate 210 is oriented toward the first substrate 110. Thus, in some embodiments, the first zone 311 and the third zone 323 may be adjacent to each other or disposed across from each other in the horizontal direction D1, and the second zone 312 and the fourth zone 324 may be adjacent to each other or disposed across from each other in the horizontal direction D1. That is, the first zone 311 and the third zone 323 may be disposed to face each other and to be connected by the shortest distance therebetween, and the second zone 312 and the fourth zone 324 may be disposed to face each other and to be connected by the shortest distance therebetween. Thus, the first zone 311 to the fourth zone 324 may be disposed such that the first routing R1 connecting the first zone 311 to the third zone 323 and the second routing R2 connecting the second zone 312 to the fourth zone 324 have the shortest distances, respectively, without intersecting each other.

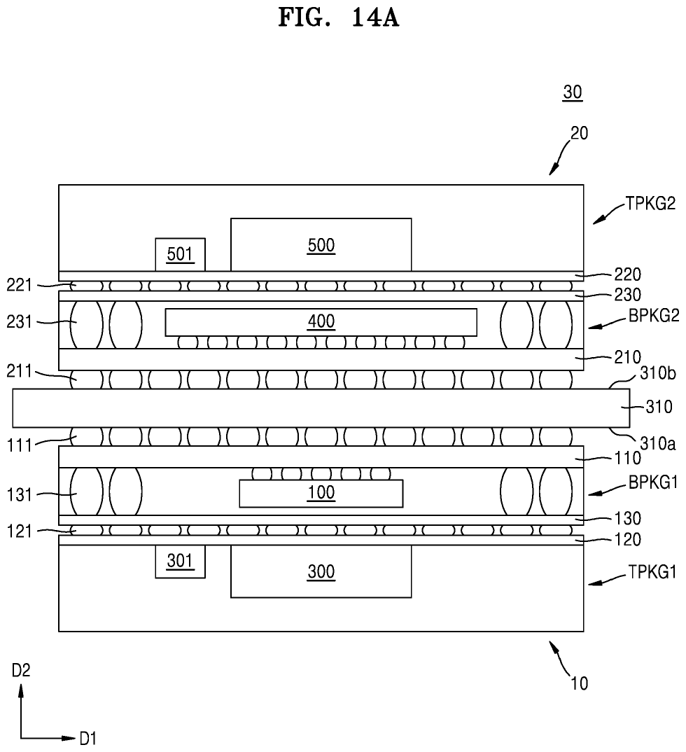

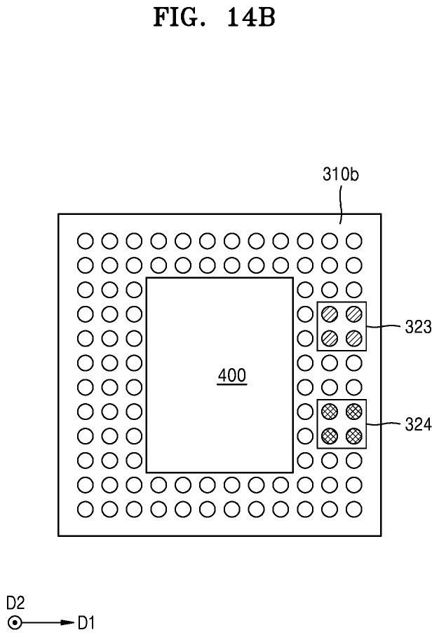

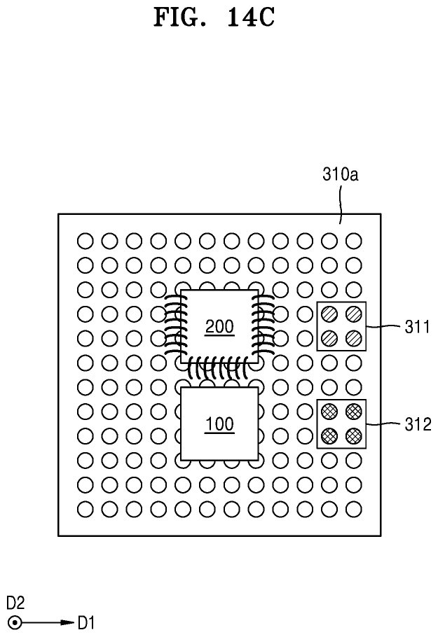

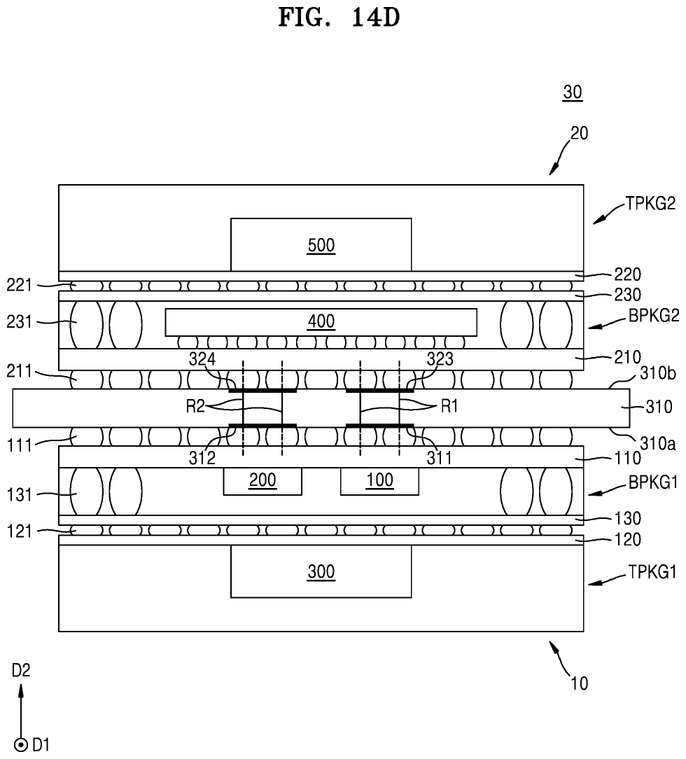

FIGS. 14A through 14D are views related to a package module according to another embodiment of the disclosure. FIG. 14A is a cross-sectional view of a package module according to another embodiment of the disclosure. FIGS. 14B and 14C are schematic plane views of some components of a package module according to embodiments of the disclosure shown in FIG. 14A. FIG. 14D is a cross-sectional view viewed from a direction different from a package module according to an embodiment of the disclosure shown in FIG. 14A.

Referring to FIG. 14A, in the package module 30 according to an embodiment of the disclosure, the first package 10 and the second package 20 may be mounted on different surfaces of the system board 310. That is, the first package 10 may be disposed on a first surface 310a of the system board 310, and the second package 20 may be disposed on a second surface 310b facing a first surface 310a in the vertical direction D2.

Referring to FIGS. 14B and 14C, in embodiments, the system board 310 may include a plurality of pads which may include the plurality of first pads 315 for connection to the first substrate 110 disposed on the first surface 310a of the system board 310 and the plurality of second pads 316 for connection to the third substrate 210 disposed on the second surface 310b of the system board 310. The system board 310 may include the first zone 311 in which some of the plurality of first pads 315 are disposed, the second zone 312 in which some others of the plurality of first pads 315 are disposed, the third zone 323 in which some of the plurality of second pads 316 are disposed, and the fourth zone 324 in which some others of the plurality of second pads 316 are disposed.

Referring to FIGS. 14A to 14D together, in the package module 30 according to another embodiment of the disclosure, the plurality of first pads 315 and the plurality of second pads 316 may be formed on the first surface 310a of the system board 310, and the first zone 311 to the fourth zone 324 may be formed on the second surface 310b of the system board 310.

In some embodiments, the first zone 311 of the first surface 310a may be electrically connected to the first vertical connection member 131 that transmits and receives a data signal and/or control signal of the third die 300, through the first substrate 110, and the third zone 323 of the second surface 310b may be electrically connected to the second vertical connection member 231 that transmits and receives a data signal and/or control signal of the fifth die 500, through the third substrate 210.

The first zone 311, the second zone 312, the third zone 323, and the fourth zone 324 may be respectively disposed on the same side in the horizontal direction D1 with respect to the first, second, and fourth dies 100, 200, and 400. That is, the first zone 311 may be disposed to overlap the third zone 323 in the vertical direction D2, and the second zone 312 may be disposed to overlap the fourth zone 324 in the vertical direction D2.

The first zone 311 and the third zone 323 are connected by first routing R1 in the system board 310, the second zone 312 and the fourth zone 324 are connected by second routing R2 in the system board 310, and the first routing R1 and the second routing R2 may not intersect each other.

In embodiments, the distance between the first zone 311 and the third zone 323 may be shorter than the distance between the first zone 311 and the fourth zone 324, and the distance between the second zone 312 and the fourth zone 324 may be shorter than the distance between the second zone 312 and the third zone 323. That is, the first zone 311 to the fourth zone 324 may be disposed such that the first zone 311 and the third zone 323 are connected by the shortest distance, and the second zone 312 and the fourth zone 324 are connected by the shortest distance.

In some embodiments where the first package 10 and the second package 20 are disposed on different surfaces of the system board 310, the first zone 311 may be disposed to overlap the third zone 323 in the vertical direction D2 and the second zone 312 may be disposed to overlap the fourth zone 324 in the vertical direction D2. That is, the first zone 311 and the third zone 323 may be disposed to face each other in the vertical direction D2 and to be connected by the shortest distance therebetween, and the second zone 312 and the fourth zone 324 may be disposed to face each other in the vertical direction D2 and to be connected by the shortest distance therebetween. Thus, the first zone 311 to the fourth zone 324 may be disposed such that the first routing R1 connecting the first zone 311 to the third zone 323 and the second routing R2 connecting the second zone 312 to the fourth zone 324 have the shortest distances, respectively, without intersecting each other.

While the inventive concept has been particularly shown and described with reference to embodiments thereof, it will be understood that various changes in form and details may be made therein without departing from the spirit and scope of the following claims.

What is claimed is:

1. A package-on-package (PoP) comprising:
a lower package;
an upper package disposed over the lower package;
an interposer substrate disposed between the lower package and the upper package; and
a plurality of balls connecting the interposer substrate to the upper package,
wherein the lower package comprises:
a first substrate;
a first die and a second die, the first and the second dies being disposed side by side in a horizontal direction, and disposed on the first substrate;
a vertical connection member electrically connecting the first substrate to the interposer substrate, and disposed between the first substrate and the interposer substrate; and
a molding layer covering the first die, the second die, and the vertical connection member,
wherein the upper package comprises:
a second substrate;
a third die disposed over the second substrate; and
a plurality of ball pads disposed on a surface of the second substrate, the plurality of ball pads corresponding to a package ball map comprising cells forming a plurality of rows and a plurality of columns, wherein one signal is placed in each of the cells,
the plurality of balls are attached on a bottom surface of the plurality of ball pads,
the interposer substrate comprises on a surface thereof a plurality of ball lands to which the plurality of balls are attached, and
at least a portion of the plurality of ball lands overlap the first and the second dies in a vertical direction that intersects the horizontal direction.

2. The PoP of claim 1, wherein the first die comprises a modem die, the second die comprises a dynamic random access memory (DRAM) die, and the lower package is a system-in-package (SIP).

3. The PoP of claim 1, wherein the vertical connection member is configured so that a data signal and/or a control signal of the third die are transmitted and received through the vertical connection member, and
the data signal and/or the control signal of the third die transmitted and received through the vertical connection member are not electrically connected to the first and the second dies in the interposer substrate and the lower package.

4. The PoP of claim 1, wherein the plurality of ball lands comprise a power ball land to which a power ball for transmitting and receiving a power signal of the third die is attached and a ground ball land to which a ground ball for transmitting and receiving a ground signal of the third die is attached,
the power signal of the third die is combined with or split from a power signal of the lower package, and
the ground signal of the third die is combined with a ground signal of the lower package.

5. The PoP of claim 1, wherein the first die is attached to the first substrate through a first bump in a flip-chip structure, and
the second die is attached to the first substrate through a second bump in the flip-chip structure.

6. The PoP of claim 1, wherein the first die is attached to the first substrate through a bump in a flip-chip structure, and
the second die is attached to the first substrate through a bonding wire.

7. The PoP of claim 1, wherein the first die is attached to the first substrate through a first bonding wire, and
the second die is attached to the first substrate through a second bonding wire.

8. The PoP of claim 1, wherein the interposer substrate comprises a printed circuit board (PCB) or a redistributed layer (RDL).

9. The PoP of claim 1, wherein the upper package further comprises a memory controller attached to the second substrate and configured to control an operation of the third die, and the third die comprises a memory die.

10. A package-on-package (PoP) comprising:
a lower package;
an upper package disposed over the lower package;
an interposer substrate disposed between the lower package and the upper package; and
a plurality of balls connecting the interposer substrate to the upper package,
wherein the lower package comprises:
a first substrate;
a first die and a second die, the first and the second dies being disposed side by side in a horizontal direction, and disposed over the first substrate;
a vertical connection member electrically connecting the first substrate to the interposer substrate, and disposed between the first substrate and the interposer substrate; and
a molding layer covering the first die, the second die, and the vertical connection member,
wherein the upper package comprises:
a second substrate;
a third die disposed over the second substrate; and
a plurality of ball pads disposed on a surface of the second substrate, the plurality of ball pads corresponding to a package ball map comprising cells forming a plurality of rows and a plurality of columns, wherein one signal is placed in each of the cells,
the plurality of balls are attached on a bottom surface of the plurality of ball pads,
the interposer substrate comprises on a surface thereof a plurality of ball lands to which the plurality of balls are attached, and
the vertical connection member is configured so that a data signal and/or a control signal of the third die are transmitted and received through the vertical connection member, and
the data signal and/or the control signal of the third die transmitted and received through the vertical connection member are not electrically connected to the first and the second dies in the interposer substrate and the lower package, and
at least a portion of the plurality of the ball lands overlap the first and the second dies in a vertical direction.

11. The PoP of claim 10, wherein the first die is attached to the first substrate through a bump in a flip-chip structure, and
the second die is stacked on the first die in the vertical direction, and is electrically connected to the first substrate through a bonding wire.

12. The PoP of claim 10, wherein the first substrate comprises a plurality of signal pads electrically connected to the first and the second dies, the plurality of signal pads being disposed on the surface of the first substrate, and
at least two first signal pads connected to the first die and at least two second signal pads connected to the second die, the at least two first signal and the at least two second signal pads being among the plurality of signal pads, and configured to transmit and receive data signals between the first and the second dies, and
the second die comprises:
at least two die pads for connection to the at least two second signal pads; and
a mode swap pad configured to transmit and receive a mode swap signal for swapping an order of data signals transmitted and received through the at least two die pads.

13. A package module comprising:
a system board; and
a first package and a second package, the first and the second packages being attached to the system board,
wherein the first package comprises a first lower package, a first upper package disposed over the first lower package, and a first interposer substrate disposed between the first lower package and the first upper package, and
the second package comprises a second lower package, a second upper package disposed over the second lower package, and a second interposer substrate disposed between the second lower package and the second upper package, and
the first lower package comprises:
a first substrate;
a first die and a second die, the first and the second dies being disposed over the first substrate; and
a first vertical connection member electrically connecting the first substrate to the interposer substrate, and disposed between the first substrate and the interposer substrate, and
the first upper package comprises a second substrate and a third die disposed over the second substrate, and
the second lower package comprises:
a third substrate;
a fourth die stacked over the third substrate; and
a second vertical connection member electrically connecting the third substrate to the second interposer substrate, and disposed between the third substrate and the second interposer substrate, and
the second upper package comprises a fourth substrate and a fifth die disposed over the fourth substrate, and
the system board comprises a first zone in which at least one of a plurality of first pads for connection to the first substrate are disposed, a second zone in which others of the plurality of first pads are disposed,
a third zone in which at least one of a plurality of second pads for connection to the third substrate are disposed, and a fourth zone in which others of the plurality of second pads are disposed, and
the first zone and the third zone are connected by a first routing in the system board, and the second zone and the fourth zone are connected by a second routing in the system board, and
the first routing does not intersect the second routing.

14. The package module of claim 13, wherein the first lower package is a system-in-package (SiP) comprising a modem die and a dynamic random access memory (DRAM) die, and
the first upper package further comprises a memory die and a memory controller configured to control an operation of the memory die.

15. The package module of claim 13, wherein the second lower package is an application processor (AP) or a system-on-chip (SoC), and
the second upper package further comprises a memory die and a memory controller configured to control an operation of the memory die.

16. The package module of claim 13, wherein a distance between the first zone and the third zone is less than a distance between the first zone and the fourth zone, and
a distance between the second zone and the fourth zone is less than a distance between the second zone and the third zone.

17. The package module of claim 13, wherein the first zone is electrically connected to the first vertical connection member configured to transmit and receive a data signal and/or a control signal of the third die through the first substrate, and
the third zone is electrically connected to the second vertical connection member configured to transmit and receive a data signal and/or a control signal of the fifth die through the third substrate.

18. The package module of claim 13, wherein the first package and the second package are disposed side by side in a first horizontal direction on a surface of the system board,
the first zone and the second zone are disposed at a side of the first substrate, directed toward the third substrate,
the third zone and the fourth zone are disposed at a side of the third substrate, directed toward the first substrate,
the first zone is adjacent to the third zone in the first horizontal direction, and
the second zone is adjacent to the fourth zone in the first horizontal direction.

19. The package module of claim 13, wherein the first package is disposed on a first surface of the system board,
the second package is disposed on a second surface opposite to the first surface of the system board in a vertical direction,
the first zone overlaps the third zone in the vertical direction, and
the second zone overlaps the fourth zone in the vertical direction.

20. The package module of claim 13, wherein the interposer substrate comprises a printed circuit board (PCB) or a redistributed layer (RDL).
